(19) United States
(12) Patent Application Publication
(10) Pub. No.: US 2011/0143497 A1
(43) Pub. Date: Jun. 16, 2011

(54) THICK FILM CONDUCTIVE COMPOSITION USED IN CONDUCTORS FOR PHOTOVOLTAIC CELLS

(75) Inventors: Shigendo Enomoto, Kawasaki (JP); Takuya Konno, Kanagawa (JP); Brian J. Laughlin, Apex, NC (US); Hisashi Matsuno, Tokyo (JP); Chun-Kwei Wu, Taoyuan (TW)

(73) Assignee: E. I. DU PONT DE NEMOURS AND COMPANY, Wilmington, DE (US)

(21) Appl. No.: 12/968,419

(22) Filed: Dec. 15, 2010

Related U.S. Application Data
(60) Provisional application No. 61/286,968, filed on Dec. 16, 2009.
(60) Provisional application No. 61/371,854, filed on Aug. 9, 2010.

(51) Int. Cl. H01L 31/18; H01B 1/12

(52) U.S. Cl. 438/98; 252/519.3; 257/E31.124

(57) ABSTRACT

A method of forming a photovoltaic cell conductor that comprises steps of, applying on a semiconductor substrate a thick film conductive composition comprising inorganic powders comprising electrically conductive powder, first glass frit and second glass frit, and organic medium, wherein total PbO in the glass frits is 80.5 to 83.5 wt % based on the total weight of the first glass frit and the second glass frit, and firing the thick film conductive composition applied on the semiconductor substrate.

### FIELD OF THE INVENTION

Embodiments of the invention relate to a thick film conductive composition used in a conductor of a photovoltaic cell device.

### TECHNICAL BACKGROUND OF THE INVENTION

A conductor of a silicon photovoltaic cell in general is required to give high efficiency to a photovoltaic cell.

US 20060102228 discloses a photovoltaic cell contact made from a mixture wherein the mixture comprises a solids portion and an organic portion, wherein the solids portion comprises a silver powder and a glass frit wherein the glass frit comprises from about 15 to about 75 mol % PbO, from about 5 to about 50 mol % SiO₂, and preferably with no B₂O₃.

### SUMMARY OF THE INVENTION

An objective is to provide a method of forming a photovoltaic cell conductor that could improve a light energy conversion efficiency of a photovoltaic cell.

An aspect relates to a method of forming a photovoltaic cell conductor comprising steps of: applying on a semiconductor substrate a thick film conductive composition containing inorganic powders including electrically conductive powder, first glass frit and second glass frit, and organic medium, wherein total PbO in the glass frits is 80.5 to 83.5 wt % based on the total weight of the first glass frit and the second glass frit, and firing the thick film conductive composition.

Another aspect relates to a thick film conductive composition comprising: inorganic powders containing electrically conductive powder, first glass frit and second glass frit, and organic medium, wherein total PbO in the composition of the glass frits is in the range of 80.5 to 83.5 wt % based on the total weight of the first glass frit and the second glass frit.

A conductor formed by the present invention can have an improved electric property to have a higher light energy conversion efficiency of a photovoltaic cell.

### BRIEF DESCRIPTION OF THE DRAWINGS

FIG. 1A to 1F are drawings for explaining a photovoltaic cell conductor production process.

### DETAILED DESCRIPTION OF THE INVENTION

A method of forming a photovoltaic cell conductor is explained below. In an embodiment of the present invention, the photovoltaic cell conductor can be formed in a p-type base photovoltaic cell in which a p-type silicon layer is used as a base as explained below.

### (Description of Method of Manufacturing a Semiconductor Device)

The following shows an embodiment of manufacturing process of a silicon type photovoltaic cell using the method for manufacturing a photovoltaic cell conductor of the present invention.

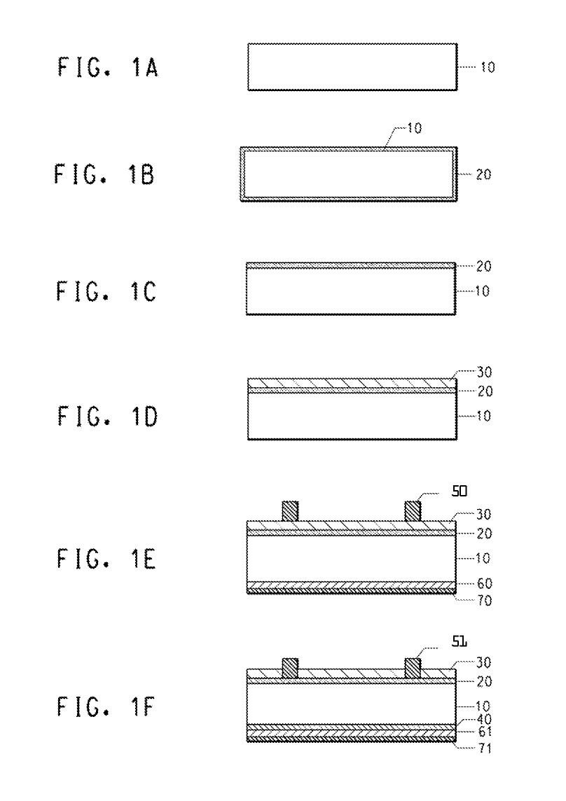

FIG. 1A shows a p-type silicon substrate 10. In FIG. 1B, an n-layer 20, of the reverse conductivity type is formed by the thermal diffusion of phosphorus (P) or the like. Phosphorus oxychloride (POCl₃) is commonly used as the phosphorus diffusion source. In the absence of any particular modification, n-layer 20 is formed over the entire surface of the silicon substrate 10. The silicon wafer consists of p-type substrate 10 and n-layer 20 typically has a sheet resistivity on the order of several tens of ohms per square (ohm/□).

After protecting one surface of the n-layer with a resist or the like, the n-layer 20 is removed from most surfaces by etching so that it remains only on one main surface as shown in FIG. 1C. The resist is then removed using an organic solvent or the like.

Next, a passivation layer 30 can be formed on the n-layer 20 as shown in FIG. 1D by a process such as plasma chemical vapor deposition (CVD). SiNₓ, TiO₂, Al₂O₃, SiOₓ or ITO could be used as a material for a passivation layer. Most commonly used is Si₃N₄. The passivation layer is sometimes called anti-reflection layer, especially it is formed on the front side that is the light receiving side of the semiconductor substrate.

As shown in FIG. 1E, thick film conductive composition 50 for the front conductor is applied on the passivation layer 30 formed on the silicon substrate then dried. Aluminum paste, 60, and silver paste, 70, are screen printed onto the back side of the substrate, 10, and successively dried. The back side conductive layers may be two layers which comprise different metal respectively.

Firing is then carried out in an infrared furnace at a temperature range of 450° C. to 1000° C. Firing total time can be from 30 seconds to 5 minutes. At firing temperature of over 1000° C. or at a firing time of more than 5 minutes damage may occur to a semiconductor substrate.

In another embodiment of the present invention, firing profile may be 10-60 seconds at over 400° C. and 2 to 10 seconds at over 600° C. Firing peak temperature is lower than 950° C. in another embodiment.

Firing peak temperature is lower than 800° C. in another embodiment. Less firing temperature is adapted in an embodiment since the lower temperature would give less damage to a semiconductor substrate. Consequently a superior electrical property of a photovoltaic cell could be expected due to low firing temperature for forming a photovoltaic cell conductor.

As shown in FIG. 1F, during firing, aluminum diffuses as an impurity from the aluminum paste into the silicon substrate, 10, on the back side, thereby forming a p+ layer, 40, containing a high aluminum dopant concentration. Firing converts the dried aluminum paste, 60, to an aluminum back conductor, 61. The backside silver paste, 70, is fired at the same time, becoming a silver back conductor, 71. During firing, the boundary between the backside aluminum and the backside silver assumes the state of an alloy, thereby achieving electrical connection. Most areas of the back conductor are occupied by the aluminum conductor, partly on account of the need to form a p+ layer, 40. At the same time, because soldering to an aluminum conductor is not easy, the silver paste, 70, is used to form a backside conductor, 71, on limited areas of the backside as a conductor for interconnecting photovoltaic cells by means of copper ribbon or the like.

On the front side, the front conductor, 51, is made of the thick film conductive composition, 50, which is capable of fire through the passivation layer, 30, during firing to achieve electrical contact with the n-type layer, 20. The present invention may be used to form the front conductor, 51. This fired-through state, i.e., the extent to which the conductive paste on the front melts and passes through the passivation layer, 30, depends on the quality and thickness of the passivation layer, 30, thick film conductive composition, 50, and on firing conditions. The conversion efficiency and moisture resistance reliability of the photovoltaic cell clearly depend, to a large degree, on this fired-through state.

In another embodiment of the present invention, the thick film conductive composition of the present invention can be applied as aluminum paste, 60, to form aluminum back conductor, 61.

In another embodiment of the present invention, the thick film conductive composition can be applied as backside silver paste, 70, to form silver back conductor, 71.

In an embodiment, the passivation layer 30 on a semiconductor substrate can be omitted. In this case, the thick film conductive composition can be applied directly on a semiconductor substrate.

In another embodiment, the thick film conductive composition of the present invention can be applied to a single-layer conductor formed on the backside of the semiconductor substrate. In another embodiment, the thick film conductive composition to form the single-layer conductor includes both of silver powder and aluminum powder as conductive material.

Additional substrates, devices, methods of manufacture, and the like, which may be utilized with the thick film compositions described herein are described in US patent application publication numbers US 2006/0231801, US 2006/0231804, and US 2006/0231800, which are hereby incorporated herein by reference in their entireties.

### (Thick Film Conductive Composition)

The thick film conductive composition used in the above mentioned method is explained in detail below. The thick film conductive composition contains at least inorganic powders including a conductive powder and two kinds of glass frit, and an organic medium. In an embodiment, the inorganic powders can be 50 to 95 wt % based on the total weight of the in the thick film conductive composition. And in an embodiment, the organic medium can be 5 to 50 wt % based on the total weight of the thick film conductive composition in order to obtain good wetting.

### (Conductive Powder)

Conductive powder is one of the inorganic powders. The conductive powder has an electrical conductivity.

The conductive powder can be one or more metal powders selected from a group consisting of (1) aluminum (Al), copper (Cu), gold (Au), silver (Ag), palladium (Pd) and platinum (Pt); (2) alloy of Al, Cu, Au, Ag, Pd or Pt; and (3) mixtures thereof. In an embodiment, the conductive powder can be one or more metal powder selected from a group consisting of Ag, Al, Cu, Au, Pd, Pt and mixture thereof. In another embodiment, the conductive powder can be Ag powder or Al powder. In another embodiment, the conductive powder can be Ag powder and Al powder. In an embodiment, the conductive powder can be Ag powder.

The particle size of the conductive powder is not subject to any particular limitation. In an embodiment, an average particle diameter of the conductive powder can be no more than 10 μm, in another embodiment no more than 5 μm, in another embodiment no more than 3 μm. In an embodiment, an average particle diameter of the conductive powder can be at least 0.1 μm, and, in another embodiment at least 1.0 μm, in another embodiment at least 1.5 μm. The average particle diameter represents D50 as measured by Microtrac (MT3100II, Microtrac Co., Ltd.). The particle diameter D50 represents the particle diameter corresponding to 50% of the integrated value of the number of particles when the particle size distribution is prepared.

The amount of the conductive powder can be measured with volume percent (vol %) based on the total volume of the inorganic powders. The volume percent of the conductive powder can be gotten by weight (g) divided by density (g/cm³) of the conductive powder and further divided by the total volume of the inorganic powders.

The conductive powder can be 70 to 92 vol % based on the volume of the inorganic powder in the composition. In an embodiment, the conductive powder can be 78 to 90 vol % based on the total volume of the inorganic powders in the thick film conductive composition. In another embodiment, the conductive powder can be 80 to 85 vol % based on the total volume of the inorganic powders in the thick film conductive composition. Conductivity of a photovoltaic cell conductor formed with the thick film conductive composition could have sufficient conductivity when the composition contains conductive powder 70 vol % or more. The conductive composition containing the conductive powder 92 vol % or lower could have sufficient viscosity enough to smoothly apply the composition on a substrate.

### (Glass Frits)

Glass frit is one of the inorganic powders. The glass frit conductive powder has an electrical conductivity.

The thick film conductive composition contains a mixture of glass frits. The mixture preferably contains at least two kinds of glass frits (also termed glass compositions) that are first glass frit and second glass frit.

In an embodiment, the first glass frit composition described herein can include one or more of SiO₂, B₂O₃, Al₂O₃, PbO, Bi₂O₃, ZnO, ZrO₂, and TiO₂. In another embodiment, the first glass frit composition described herein can include one or more of SiO₂, B₂O₃, Al₂O₃, PbO, and ZrO₂. Unless stated otherwise, as used herein, wt % means wt % of glass composition only.

In an embodiment, SiO₂ in the first glass frit composition can be 8 to 40 wt %, in another embodiment 10 to 35 wt %, in another embodiment 10 to 30 wt %.

In an embodiment, B₂O₃ in the first glass frit composition can be 0 to 10 wt %, in another embodiment 0 to 8 wt %, in another embodiment 1 to 10 wt %.

In an embodiment, Al₂O₃ in the first glass frit composition can be 0 to 5.0 wt %, in another embodiment 0.1 to 3.0 wt %, in another embodiment 0.2 to 1.5 wt %;

In an embodiment, PbO in the first glass frit composition can be 60 to 80 wt %, in another embodiment less than 64 to 79 wt %, in another embodiment 69 to 78 wt %.

In an embodiment, ZrO₂ in the first glass frit composition can be 0 to 3 wt %, in another embodiment 0.1 to 2.0 wt %, in an embodiment 0.2 to 1.0 wt %.

In an embodiment, Bi₂O₃ in the first glass frit composition can be 0 to 10 wt %, in another embodiment 1 to 8 wt %, in another embodiment 4 to 7 wt %.

In an embodiment, ZnO in the first glass frit composition can be 0 to 10 wt %, in another embodiment 1 to 7 wt %, in another embodiment 3 to 5 wt %.

In an embodiment, TiO₂ in the first glass frit composition can be 0 to 10 wt %, in another embodiment 1 to 7 wt %, in another embodiment 3 to 5 wt %.

In an embodiment, PbF2 in the first glass frit composition can be a complete or partial substitute for PbO.

In an embodiment, the first glass frit can have a softening point of less than 650° C., in another embodiment less than 610° C., in another embodiment less than 598° C.

In an embodiment, the second glass frit composition described herein can include one or more of SiO₂, B₂O₃, Al₂O₃, PbO, Bi₂O₃, ZnO, ZrO₂, and TiO₂. In another embodiment, the first glass frit composition described herein can include one or more of SiO₂, B₂O₃, Al₂O₃, PbO, and ZrO₂.

Unless stated otherwise, as used herein, wt % means wt % of glass composition only.

In an embodiment, SiO₂ in the second glass frit composition can be 5 to 30 wt %, in another embodiment 7 to 25 wt %, in another embodiment 10 to 20 wt %.

In an embodiment, B₂O₃ in the second glass frit composition can be 0 to 10 wt %, in another embodiment 0 to 8 wt %, in another embodiment 1 to 10 wt %.

In an embodiment, Al₂O₃ in the second glass frit composition can be 0 to 5.0 wt %, in another embodiment 0.1 to 3.0 wt %, in another embodiment 0.2 to 0.8 wt %.

In an embodiment, PbO in the second glass frit composition can be 80 to 96 wt %, in another embodiment 81 to 90 wt %, in another embodiment 83 to 88 wt %.

In an embodiment, ZrO₂ in the second glass frit composition can be 0 to 3 wt %, in another embodiment 0.1 to 1.5 wt %, in an embodiment 0.2 to 0.5 wt %.

In an embodiment, Bi₂O₃ in the second glass frit composition can be 0 to 10 wt %, in another embodiment 1 to 8 wt %, in another embodiment 4 to 7 wt %.

In an embodiment, ZnO in the second glass frit composition can be 0 to 10 wt %, in another embodiment 1 to 7 wt %, in another embodiment 3 to 5 wt %.

In an embodiment, TiO₂ in the second glass frit composition can be 0 to 10 wt %, in another embodiment 1 to 7 wt %, in another embodiment 3 to 5 wt %.

In an embodiment, softening point of the first glass frit is at least 450° C., in another embodiment 480° C., in another embodiment 500° C. In an embodiment, softening point of the first glass frit is 600° C. or lower. PbO in the glass frits is at least 80.5 wt % based on the total weight of the first glass frit and the second glass frit. In an embodiment, PbO in the glass frits is at least 80.7 wt % based on the total weight of the first glass frit and the second glass frit. In the present invention, PbO in the glass frits is no more than 83.5 wt % based on the total weight of the first glass frit and the second glass frit. In an embodiment, PbO in the glass frits is no more than 83.0 wt %, in another embodiment 82.5 wt %, based on the total weight of the first glass frit and the second glass frit. When PbO in the glass frits is too much or too short, electrical property of a conductor might not be improved.

The amount of the each of the first glass frit and the second glass frit can take volume percent (vol %) based on the total volume of the first glass frit and the second glass frit. With volume percent, first glass frit and the second glass frit can be used with the same amount in any combination despite of different glass compositions that can have different density. The volume percent of the glass frit can be gotten by weight (g) divided by density (g/cm³) of the glass frit conductive powder and further divided by the total volume of the first glass frit and the second glass frit. The glass densities in Table 2 are the values of the measured weight of a glass cube with size 1 cm×1 cm×1 cm.

In an embodiment, the first glass frit plus the second glass frit can be 4 to 30 vol % based on the volume of the inorganic powders in the composition. In another embodiment, the first glass frit plus the second glass frit can be 6 to 20 vol %, in another embodiment 8 to 15 vol %, based on the total volume of the inorganic powders in the thick film conductive composition. Conductivity of a photovoltaic cell conductor could have sufficient conductivity when containing the glass frit 30 vol % or less. The conductive composition containing the glass frit 4 vol % or more could have sufficient adhesion to a semiconductor substrate.

In an embodiment, softening point of the second glass frit is at least 350° C., in another embodiment 380° C., in another embodiment 410° C.

In an embodiment, softening point of the second glass frit can be at least 40° C. lower than the softening point of the first glass frit, in another embodiment 45° C. lower than the softening point of the first glass frit.

The first glass frit and the second glass frit can be selected from compositions listed in Table 1. The glass compositions listed in Table I are not limiting, it is contemplated that one of ordinary skill in the art of glass chemistry could make minor substitutions of additional ingredients and not substantially change the desired properties of the glass composition.

TABLE 1

| Glass | wt % | | | | | | | | | | | |
|---|---|---|---|---|---|---|---|---|---|---|---|---|
| No. | SiO₂ | Al₂O₃ | PbO | B₂O₃ | Na₂O | Li₂O | ZrO₂ | Bi₂O₃ | TiO₂ | CuO | PbF₂ | P2O5 |
| 1 | 18.95 | 0.96 | 56.39 | 1.92 | | | 0.48 | | | | 21.29 | |
| 2 | 12.83 | 0.37 | 65.14 | | | | 0.37 | | | | 21.29 | |
| 3 | 18.89 | 0.95 | 56.21 | 1.92 | 0.11 | 0.21 | 0.48 | | | | 21.23 | |
| 4 | 12.80 | 0.37 | 64.96 | | 0.09 | 0.18 | 0.37 | | | | 21.24 | |
| 5 | 18.95 | 0.96 | 52.90 | 1.92 | | | 0.48 | | | | 24.79 | |
| 6 | 12.83 | 0.37 | 61.64 | | | | 0.37 | | | | 24.79 | |
| 7 | 18.89 | 0.95 | 52.71 | 1.92 | 0.11 | 0.21 | 0.48 | | | | 24.73 | |
| 8 | 12.80 | 0.37 | 61.45 | | 0.09 | 0.18 | 0.37 | | | | 24.74 | |
| 9 | 15.42 | 0.20 | 79.71 | 1.82 | 0.10 | 0.20 | 0.41 | | | 2.15 | | |
| 10 | 19.16 | 0.97 | 64.90 | 1.94 | | | 0.49 | | | | 12.54 | |
| 11 | 12.97 | 0.37 | 73.76 | | | | 0.37 | | | | 12.53 | |
| 12 | 29.21 | 0.49 | 45.01 | | | | 0.50 | | | | 24.79 | |
| 13 | 29.54 | 0.50 | 56.92 | | | | 0.51 | | | | 12.53 | |
| 14 | 21.20 | 0.37 | 31.95 | 7.19 | 0.13 | 0.25 | | 6.53 | 5.64 | 2.65 | 24.09 | |
| 15 | 21.79 | 0.38 | 32.93 | 7.39 | 0.13 | 0.25 | | 6.71 | 5.78 | | 24.66 | |
| 16 | 22.26 | 0.39 | 43.56 | 7.54 | 0.13 | 0.25 | | 6.85 | 2.10 | 2.62 | 14.31 | |
| 17 | 22.86 | 0.40 | 44.83 | 7.75 | 0.13 | 0.25 | | 7.04 | 2.15 | | 14.60 | |
| 18 | 15.45 | 0.42 | 50.88 | 3.30 | | | | 7.40 | 6.38 | | 9.45 | 6.73 |
| 19 | 21.25 | 0.37 | 44.93 | 3.60 | | | | 6.54 | 5.64 | | 10.32 | 7.35 |
| 20 | 20.48 | 0.36 | 43.31 | | | | | 6.30 | 5.43 | | 9.95 | 14.16 |
| 21 | 19.10 | 0.97 | 64.69 | 1.93 | 0.11 | 0.21 | 0.49 | | | | 12.50 | |
| 22 | 12.93 | 0.37 | 73.55 | | 0.10 | 0.18 | 0.37 | | | | 12.50 | |
| 23 | 15.81 | 0.65 | 69.41 | 0.90 | 0.10 | 0.19 | 0.43 | | | | 12.50 | |
| 24 | 15.77 | 0.41 | 69.03 | 1.88 | | | 0.41 | | | | 12.50 | |
| 25 | 15.84 | 0.41 | 69.31 | 1.89 | | | | | | | 12.55 | |
| 26 | 15.76 | 0.87 | 69.00 | 1.88 | | | | | | | 12.49 | |
| 27 | 15.69 | 1.34 | 68.67 | 1.87 | | | | | | | 12.43 | |
| 28 | 20.15 | 0.26 | 79.08 | | | | 0.51 | | | | | |
| 29 | 24.20 | 0.46 | 74.94 | | | | 0.40 | | | | | |
| 30 | 17.58 | 0.41 | 81.65 | | | | 0.36 | | | | | |
| 31 | 14.78 | 0.39 | 84.49 | | | | 0.34 | | | | | |
| 32 | 19.60 | 0.99 | 76.93 | 1.99 | | | 0.50 | | | | | |
| 33 | 17.45 | 1.17 | 81.03 | | | | 0.36 | | | | | |
| 34 | 12.80 | 0.40 | 81.43 | 4.96 | | | 0.40 | | | | | |
| 35 | 15.77 | 0.41 | 81.53 | 1.88 | | | 0.41 | | | | | |
| 36 | 11.32 | 0.37 | 86.06 | 1.89 | | | 0.37 | | | | | |
| 37 | 13.27 | 0.38 | 85.97 | | | | 0.38 | | | | | |
| 38 | 28.40 | 3.73 | 67.87 | | | | | | | | | |
| 39 | 29.21 | 0.49 | 69.80 | | | | 0.50 | | | | | |
| 40 | 15.66 | 0.42 | 81.00 | 1.88 | 0.21 | 0.40 | 0.42 | | | | | |
| 41 | 15.72 | 0.42 | 81.28 | 1.86 | 0.10 | 0.20 | 0.42 | | | | | |
| 42 | 15.76 | 0.20 | 81.46 | 1.86 | 0.10 | 0.20 | 0.42 | | | | | |
| 43 | 19.73 | 0.22 | 77.61 | 1.98 | | | 0.46 | | | | | |
| 44 | 19.59 | 0.22 | 77.07 | 2.02 | 0.22 | 0.43 | 0.45 | | | | | |
| 45 | 19.69 | 0.22 | 77.31 | 2.00 | 0.11 | 0.22 | 0.45 | | | | | |
| 46 | 15.84 | | 81.90 | 1.84 | | | 0.42 | | | | | |
| 47 | 15.79 | | 81.63 | 1.86 | 0.10 | 0.20 | 0.42 | | | | | |
| 48 | 12.90 | 0.39 | 84.57 | 1.76 | | | 0.34 | | | | | |

The glass frits described herein is produced by a conventional glass making technique. Ingredients are weighed then mixed in the desired proportions and heated in a furnace to form a melt in platinum alloy crucibles. As well known in the art, heating is conducted to a peak temperature (800-1400° C.) and for a time such that the melt becomes entirely liquid and homogeneous. The molten glass is then quenched between counter rotating stainless steel rollers to form a 10-15 mil thick platelet of glass. The resulting glass platelet was then milled to form a powder with its 50% volume distribution set between to a desired target (e.g. 0.8 to 1.5 μm). One skilled the art of producing glass frit may employ alternative synthesis techniques such as but not limited to water quenching, sol-gel, spray pyrolysis, or others appropriate for making powder forms of glass.

Specimens of the first glass frit and the second glass frit described above on an elemental basis are shown in Table 2.

TABLE 2

| Glass | wt % | | | | | | | | | | | |
|---|---|---|---|---|---|---|---|---|---|---|---|---|
| No. | SiO₂ | Al₂O₃ | PbO | B₂O₃ | Na₂O | Li₂O | ZrO₂ | Bi₂O₃ | TiO₂ | CuO | PbF₂ | P2O5 |
| 1 | 18.95 | 0.96 | 56.39 | 1.92 | | | 0.48 | | | | 21.29 | |
| 2 | 12.83 | 0.37 | 65.14 | | | | 0.37 | | | | 21.29 | |
| 3 | 18.89 | 0.95 | 56.21 | 1.92 | 0.11 | 0.21 | 0.48 | | | | 21.23 | |
| 4 | 12.80 | 0.37 | 64.96 | | 0.09 | 0.18 | 0.37 | | | | 21.24 | |
| 5 | 18.95 | 0.96 | 52.90 | 1.92 | | | 0.48 | | | | 24.79 | |
| 6 | 12.83 | 0.37 | 61.64 | | | | 0.37 | | | | 24.79 | |
| 7 | 18.89 | 0.95 | 52.71 | 1.92 | 0.11 | 0.21 | 0.48 | | | | 24.73 | |
| 8 | 12.80 | 0.37 | 61.45 | | 0.09 | 0.18 | 0.37 | | | | 24.74 | |
| 9 | 15.42 | 0.20 | 79.71 | 1.82 | 0.10 | 0.20 | 0.41 | | | 2.15 | | |
| 10 | 19.16 | 0.97 | 64.90 | 1.94 | | | 0.49 | | | | 12.54 | |
| 11 | 12.97 | 0.37 | 73.76 | | | | 0.37 | | | | 12.53 | |
| 12 | 29.21 | 0.49 | 45.01 | | | | 0.50 | | | | 24.79 | |
| 13 | 29.54 | 0.50 | 56.92 | | | | 0.51 | | | | 12.53 | |
| 14 | 21.20 | 0.37 | 31.95 | 7.19 | 0.13 | 0.25 | | 6.53 | 5.64 | 2.65 | 24.09 | |
| 15 | 21.79 | 0.38 | 32.93 | 7.39 | 0.13 | 0.25 | | 6.71 | 5.78 | | 24.66 | |
| 16 | 22.26 | 0.39 | 43.56 | 7.54 | 0.13 | 0.25 | | 6.85 | 2.10 | 2.62 | 14.31 | |
| 17 | 22.86 | 0.40 | 44.83 | 7.75 | 0.13 | 0.25 | | 7.04 | 2.15 | | 14.60 | |
| 18 | 15.45 | 0.42 | 50.88 | 3.30 | | | | 7.40 | 6.38 | | 9.45 | 6.73 |
| 19 | 21.25 | 0.37 | 44.93 | 3.60 | | | | 6.54 | 5.64 | | 10.32 | 7.35 |
| 20 | 20.48 | 0.36 | 43.31 | | | | | 6.30 | 5.43 | | 9.95 | 14.16 |
| 21 | 19.10 | 0.97 | 64.69 | 1.93 | 0.11 | 0.21 | 0.49 | | | | 12.50 | |
| 22 | 12.93 | 0.37 | 73.55 | | 0.10 | 0.18 | 0.37 | | | | 12.50 | |
| 23 | 15.81 | 0.65 | 69.41 | 0.90 | 0.10 | 0.19 | 0.43 | | | | 12.50 | |
| 24 | 15.77 | 0.41 | 69.03 | 1.88 | | | 0.41 | | | | 12.50 | |
| 25 | 15.84 | 0.41 | 69.31 | 1.89 | | | | | | | 12.55 | |
| 26 | 15.76 | 0.87 | 69.00 | 1.88 | | | | | | | 12.49 | |
| 27 | 15.69 | 1.34 | 68.67 | 1.87 | | | | | | | 12.43 | |
| 28 | 20.15 | 0.26 | 79.08 | | | | 0.51 | | | | | |
| 29 | 24.20 | 0.46 | 74.94 | | | | 0.40 | | | | | |
| 30 | 17.58 | 0.41 | 81.65 | | | | 0.36 | | | | | |
| 31 | 14.78 | 0.39 | 84.49 | | | | 0.34 | | | | | |
| 32 | 19.60 | 0.99 | 76.93 | 1.99 | | | 0.50 | | | | | |
| 33 | 17.45 | 1.17 | 81.03 | | | | 0.36 | | | | | |
| 34 | 12.80 | 0.40 | 81.43 | 4.96 | | | 0.40 | | | | | |
| 35 | 15.77 | 0.41 | 81.53 | 1.88 | | | 0.41 | | | | | |
| 36 | 11.32 | 0.37 | 86.06 | 1.89 | | | 0.37 | | | | | |
| 37 | 13.27 | 0.38 | 85.97 | | | | 0.38 | | | | | |
| 38 | 28.40 | 3.73 | 67.87 | | | | | | | | | |
| 39 | 29.21 | 0.49 | 69.80 | | | | 0.50 | | | | | |
| 40 | 15.66 | 0.42 | 81.00 | 1.88 | 0.21 | 0.40 | 0.42 | | | | | |
| 41 | 15.72 | 0.42 | 81.28 | 1.86 | 0.10 | 0.20 | 0.42 | | | | | |
| 42 | 15.76 | 0.20 | 81.46 | 1.86 | 0.10 | 0.20 | 0.42 | | | | | |
| 43 | 19.73 | 0.22 | 77.61 | 1.98 | | | 0.46 | | | | | |
| 44 | 19.59 | 0.22 | 77.07 | 2.02 | 0.22 | 0.43 | 0.45 | | | | | |
| 45 | 19.69 | 0.22 | 77.31 | 2.00 | 0.11 | 0.22 | 0.45 | | | | | |
| 46 | 15.84 | | 81.90 | 1.84 | | | 0.42 | | | | | |
| 47 | 15.79 | | 81.63 | 1.86 | 0.10 | 0.20 | 0.42 | | | | | |
| 48 | 12.90 | 0.39 | 84.57 | 1.76 | | | 0.34 | | | | | |

### (Organic Medium)

The thick film conductive composition in the present invention include organic medium. The inorganic powders such as the Ag powder and the glass frits as described above are mixed with the organic medium, for example, by mechanical mixing to form a viscous composition called “paste”, having suitable consistency and rheology for printing.

Organic medium contains polymer and optionally solvent. Solvent can be added to the polymer to adjust viscosity or printability of the paste.

The polymer can be present in the organic medium in the range of 8 wt % to 11 wt % of the thick film conductive composition.

The ratio of organic medium in the thick film composition to the inorganic components in the dispersion can be dependent on the method of applying the paste and the kind of organic medium used, as determined by one of skill in the art.

The organic medium in the thick film conductive composition can be 5 to 50 wt % based on the total weight of the composition in order to obtain good wetting.

### (Additives)

Thickener, stabilizer, viscosity modifier or surfactant as additives may be added to the conductive paste of the present invention. Other common additives such as a dispersant, viscosity-adjusting agent, and so on can also be added. The amount of the additive depends on the desired characteristics of the resulting electrically conducting paste and can be chosen by people in the industry. The additives can also be added in multiple types.

### EXAMPLES

The present invention is illustrated by, but is not limited to, the following examples.

### (Preparation of Thick Film Conductive Composition)

The thick film conductive composition was produced using the following materials.

Conductive Powder: Silver powder was used. The shape was spherical (D50: 2.7 μm as determined with a laser scattering-type particle size distribution measuring apparatus)

Organic medium: Terpineol solution of ethyl cellulose

Additive: Viscosity modifier

First glass: Glass number 29, 32 and 39 as shown in Table 3

Second glass: Glass number 35 and 37 as shown in Table 3

TABLE 3

| | | | Glass | | | | | |
|---|---|---|---|---|---|---|---|---|
| | | Ts | density | wt % | | | | |
| Glass No. | | (° C.) | (g/cm³) | SiO₂ | Al₂O₃ | PbO | B₂O₃ | ZrO₂ |
| First | 29 | 524 | 5.6 | 24.20 | 0.46 | 74.94 | — | 0.40 |
| glass | 32 | 486 | 5.8 | 19.60 | 0.99 | 76.93 | 1.99 | 0.50 |
| | 39 | 590 | 5.0 | 29.21 | 0.49 | 69.80 | — | 0.50 |
| Second | 35 | 428 | 6.3 | 15.77 | 0.41 | 81.53 | 1.88 | 0.41 |
| glass | 37 | 437 | 6.8 | 13.27 | 0.38 | 85.97 | — | 0.38 |

The thick film conductive composition was prepared with the following procedure. The organic medium and thixatrol were weighed then mixed in a mixing can for 15 minutes, then the first glass frit and the second glass frit were weighted and added to the organic medium mixture and mixed for another 15 minutes. The combination of the glass frits and the content in volume percent (vol %) of the glass frits are shown in Table 4. PbO weight percent (wt %) based on the total weight of the glass frits are shown in Table 4. PbO wt % was a total weight of PbO in the first glass frit and the second glass frit divided by the total weight of these glass frits.

Since Ag powder was added incrementally to ensure better wetting. The Ag powder was 90 vol % or 88 vol % based on the total volume of the Ag powder and the glass frit. When well mixed, the thick film conductive composition was repeatedly passed through a 3-roll mill for at progressively increasing pressures from 0 to 400 psi. The gap of the rolls will be adjusted to 1 mil. The degree of dispersion was measured by fineness of grind (FOG). A typical FOG value was 20/10 or less for conductors.

### (Manufacture of Test Pieces)

The thick film conductive composition obtained by the above method was screen printed on a silicon wafer (38 mm×38 mm). The silicon wafer had a passivation layer (SiNx) on one side surface of the wafer. The thick film conductive composition was applied on the passivation layer. The printed pattern of conductor consists of finger lines with 0.1 μm width, 35.2 mm length and 15 μm thickness) and bus bar with 2 mm width, 34 mm length and 20 μm thickness. The interval distance between finger lines was 1.9 mm. The thick film conductive composition on the wafer was dried at 150° C. for 5 min in a convection oven. Conductors were then obtained upon being sintered in an IR heating type of belt furnace (CF-7210, Despatch industry) at varying peak temperature setting with 775° C. IN-OUT Sintering time was 60 seconds. Sintering temperature was less than 775° C., 400 to 600° C. for 15 seconds and over 600° C. for 6 seconds. The belt speed during sintering was 550 cpm.

### (Test Procedure-Efficiency)

The photovoltaic cells built according to the method described herein were tested for efficiency. The test pieces of photovoltaic cells built according to the method described herein was placed in a commercial IV tester (NCT-150AA, NPC Corporation) for measuring efficiencies. The Xe Arc lamp in the IV tester simulated the sunlight with a known intensity and radiate on the front surface of the cell. The tester will use “four contacts method” to measure current (I) and voltage (V) at approximately 400 load resistance settings to determine the cell's I-V curve. The bus bars printed on the front of the cell were connected to the multiple probes of the IV tester and the electrical signals were transmitted through the probes to the computer for calculating efficiencies.

### (Results)

The efficiency (Eff) of each test pieces is shown in Table 4. Eff of the paste 2, 6, 12 and 17 were over 16%. Comparing paste 12 and paste 17, when the paste contained 12 vol % of glass frit, Eff was sufficient.

TABLE 4

| | | | | Second glass | | Glass | | |
|---|---|---|---|---|---|---|---|---|
| | First glass frit (vol %)* | | | frit (vol %)* | | content | PbO | Eff |
| | No. 29 | No. 32 | No. 39 | No. 35 | No. 37 | (vol %)** | (wt %)*** | (%) |
| Paste 1 | 75 | — | — | — | 25 | 10 | 78.1 | 15.41 |
| Paste 2 | 50 | — | — | — | 50 | 10 | 81.0 | 16.21 |
| Paste 3 | 25 | — | — | — | 75 | 10 | 83.6 | 15.24 |
| Paste 4 | — | — | 75 | — | 25 | 10 | 74.8 | 14.45 |
| Paste 5 | — | — | 50 | — | 50 | 10 | 79.1 | 15.54 |
| Paste 6 | — | — | 25 | — | 75 | 10 | 82.8 | 16.08 |
| Paste 7 | — | — | 75 | 25 | — | 10 | 73.3 | 14.09 |
| Paste 8 | — | — | 50 | 50 | — | 10 | 77.2 | 15.63 |
| Paste 9 | — | — | 25 | 75 | — | 10 | 80.1 | 15.34 |
| Paste 10 | — | 100 | — | — | — | 10 | 76.9 | 15.76 |
| Paste 11 | — | 25 | — | — | 75 | 10 | 79.5 | 15.57 |
| Paste 12 | — | 50 | — | — | 50 | 10 | 81.8 | 16.03 |
| Paste 13 | — | 75 | — | — | 25 | 10 | 84.0 | 15.43 |
| Paste 14 | — | — | — | — | 100 | 10 | 86.0 | 14.96 |
| Paste 15 | — | 100 | — | — | — | 12 | 76.9 | 15.09 |
| Paste 16 | — | 25 | — | — | 75 | 12 | 79.5 | 15.67 |
| Paste 17 | — | 50 | — | — | 50 | 12 | 81.8 | 16.2 |
| Paste 18 | — | 75 | — | — | 25 | 12 | 84.0 | 15.2 |
| Paste 19 | — | — | — | — | 100 | 12 | 86.0 | 14.39 |

*Glass volume percent based on the total volume of the first glass frit and the second glass frit.
**Glass volume percent based on the total volume of the inorganic powders consisting of the Ag powder and the glass frits.
**PbO weight percent based on the total weight of the first glass frit and the second glass frit.

What is claimed is:

1. A method of forming a photovoltaic cell conductor comprising steps of:
applying on a semiconductor substrate a thick film conductive composition comprising inorganic powders comprising electrically conductive powder, first glass frit and second glass frit, and organic medium, wherein total PbO in the glass frits is 80.5 to 83.5 wt % based on total weight of the first glass frit and the second glass frit, and
firing the thick film conductive composition applied on the semiconductor substrate.

2. The method of forming a photovoltaic cell conductor of claim 1, wherein total volume of the first glass frit and the second glass frit is 4 to 30 vol % based on total volume of the inorganic powders in the thick film conductive composition.

3. The method of forming a photovoltaic cell conductor of claim 1, softening point of the second glass frit is at least 40° C. lower than softening point of the first glass frit.

4. The method of forming a photovoltaic cell conductor of claim 1, wherein the thick film conductive composition is fired for 30 seconds to 5 minutes.

5. A thick film conductive composition comprising:
inorganic powders comprising electrically conductive powder, first glass frit and second glass frit, and
organic medium,
wherein total PbO in the glass frits is 80.5 to 83.5 wt % based on the total weight of the first glass frit and the second glass frit.

6. The thick film conductive composition of claim 5, wherein total volume of the first glass frit and the second glass frit is 4 to 30 vol % based on total volume of the inorganic powders in the thick film conductive composition.

7. The thick film conductive composition of claim 5, wherein softening point of the second glass frit is at least 40° C. lower than softening point of the first glass frit.
